(19) United States
(12) Patent Application Publication
(10) Pub. No.: US 2008/0206953 A1
(43) Pub. Date: Aug. 28, 2008

(54) METHOD FOR MANUFACTURING SEMICONDUCTOR DEVICE

(75) Inventor: Kei KANEMOTO, Suwa (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 12/033,036

(22) Filed: Feb. 19, 2008

(30) Foreign Application Priority Data
Feb. 28, 2007 (JP) 2007-049339

(51) Int. Cl. H01L 21/762

(52) U.S. Cl. 438/413; 257/E21.545

(57) ABSTRACT

A method for manufacturing a semiconductor device having a silicon-on-insulator region and a bulk region in a same semiconductor substrate, the method including: (a) forming a protection film on the semiconductor substrate in the bulk region; (b) exposing a surface of the semiconductor substrate in the silicon-on-insulator region from under the protection film; (c) forming a first semiconductor layer and subsequently a second semiconductor layer on the semiconductor substrate in the silicon-on-insulator region and in the bulk region, using an epitaxy method after the step (a); (d) etching the first semiconductor layer and the second semiconductor layer partially, so as to form a first trench which exposes a side surface of the first semiconductor layer in the silicon-on-insulator region; (e) etching the first semiconductor layer through the first trench with an etching condition in which the first semiconductor layer is easier to be etched than the second semiconductor layer, so as to form a cavity between the semiconductor substrate and the second semiconductor layer in the silicon-on-insulator region; and (f) forming a buried insulating film inside the cavity.

The entire disclosure of Japanese Patent Application No. 2007-049339, filed Feb. 28, 2007 is expressly incorporated by reference herein.

### BACKGROUND

1. Technical Background

The present invention relates to a method for manufacturing a semiconductor device, particularly to a technique to form a silicon-on-insulator (SOI) structure on a semiconductor substrate.

2. Related Art

Examples of such method include the ones disclosed in JP-A-2005-354024, JP-A-2006-108206, and T. Sakai et al. “Separation by Bonding Si Islands (SBSI) for LSI Application” Second International SiGe Technology and Device Meeting, Meeting Abstract, pp. 230-231, May 2004. Methods disclosed therein are called the SBSI method which forms an SOI structure on a part of a bulk substrate. According to the SBSI method, a silicon (Si) layer and a silicon germanium (SiGe) layer are deposited on an Si substrate, and only the SiGe layer is then selectively removed by taking an advantage of the etching ratio variation of Si and SiGe, so as to form a cavity between the Si substrate and the Si layer. Subsequently, a top surface of the Si substrate and a bottom surface of the Si layer which are facing an interior of the cavity are thermally oxidized, so as to form an SiO₂ film (hereafter also referred to as “buried oxide (BOX) layer”) between the Si substrate and the Si layer. Thereafter, a film such as an SiO₂ film is deposited on the Si substrate with CVD method, thereafter CMP planarized and etched with solutions such as diluted hydrofluoric acid (HF), so as to expose the surface of the Si layer (hereafter also referred to as “SOI layer”) on the BOX layer.

JP-A-2006-108206 discloses a method for fabricating a bulk element and an SOI element on a same substrate using the aforementioned SBSI method. It is also conceivable that a polycrystal epitaxial film formed on an element isolation layer is used as a stopper for CMP in a subsequent process, in the preparation of a semiconductor device which includes a bulk element and an SOI element fabricated on the same substrate. A method for manufacturing a semiconductor device is as follows, the method using the above methods of fabricating an SOI element and a bulk element on a same substrate.

FIGS. 10A to 10D are sectional drawings illustrating a method for manufacturing a semiconductor device according to a related art.

In FIG. 10A, after forming an element isolation layer 107 with LOCOS method, what is removed by wet etching is only an SiO₂ film 103 in the region for forming an SOI structure with SBSI method (hereafter also referred to as “SBSI region”), and the surface of an Si substrate 101 is exposed.

Thereafter, as shown in FIG. 10B, a SiGe layer 111 and an Si layer 113 are sequentially grown with an epitaxy on the entire surface of the Si substrate (hereafter, the SiGe layer 111 and the Si layer 113 are also collectively referred to as “epitaxial film”). At this time, a single-crystalline epitaxial film 115a is formed on the Si substrate 101 within the SBSI region, and a polycrystalline epitaxial film 115b is formed on the SiO₂ film 103 within the bulk region as well as on the element isolation layer 107.

In accordance with the SBSI methods described in the above-referenced examples of related art, the following processes are carried out, including: a forming of a support hole; a forming of a support (SiO₂ film) 122; selective etching of the SiGe; a forming of the BOX layer; a deposition of an SiO₂ film for burring a hole (trench); and CMP and wet etching of the SiO₂ and the support 122. Consequently, as shown in FIG. 10C, an SOI structure is formed in the SBSI region on the Si substrate 101, and the surface of the Si layer (i.e. SOI layer) 113 is exposed from under the support 122. Here, the SOI structure includes an SiO₂ film 131 and the Si layer 113.

After the SOI structure is completed, the SBSI region is covered with a resist pattern R′ as shown in FIG. 10D, so as to carry out wet etching of the support 122 remaining in the bulk region with an etchant such as BHF. The epitaxial film 115b is then removed with plasma etching. Here, the etching selection ratio of polysilicon (poly-Si) is higher than that of the SiO₂. Therefore, the dry etching of the epitaxial film 115b is stopped at a thin SiO₂ film 103. Forming an SOI structure in the SBSI region and removing the epitaxial film 115b from the bulk region is thereby completed. Thereafter, using the common CMOS manufacturing process, elements such as CMOS are formed on the Si substrate 101 in the SBSI and the bulk regions.

In the above manufacturing method, the inventor found out that there are multiple holes h1 formed inside the epitaxial film 115b within the bulk region. The single-crystalline epitaxial film 115a is formed on the single-crystalline Si substrate 101, and the polycrystalline epitaxial film 115b is formed on the SiO₂ film 103 as well as on the element isolation layer 107. According to the inventor's finding and the subsequent research, the multiple fine holes h1 are formed in the polycrystalline epitaxial film 115b, but not in the single-crystalline epitaxial film 115a. The scale of the fine holes h1 is approximately a few tenth μm in diameter, which is the scale observable with an electron microscope. The polycrystalline epitaxial film 115b is understood to be an aggregation of particles (grains). However, the generation mechanism of those holes is not specified yet at this current stage of research, whether these fine holes h1 are “where the particles did not grow”, or “where the particles are removed” by subsequent operations such as cleaning.

If these fine holes h1 remain in the polycrystalline epitaxial film 115b, it may cause a negative effect on the yield and the reliability of a semiconductor device. That is to say, as shown in FIG. 10C, if the fine holes h1 is formed in the epitaxial film 115b within the bulk region, the support 122 that buries the holes hi and the SiO₂ film 103 present thereunder are removed, and the Si substrate 101 is exposed during the subsequent etching process using an etchant such as BHF, or, during the subsequent cleaning process. In the plasma etching process of the epitaxial film 115b, the surface of the Si substrate 101 exposed at the bottom surface of the holes h1 is etched and holes h2 are formed in the Si substrate 101 as shown in FIG. 10D. Such holes h2 may cause a leak current or a breakdown of the gate insulating film of bulk elements that are to be formed later.

### SUMMARY

An advantage of the invention is to provide a semiconductor device manufacturing method which reduces the occurrence of defects in bulk elements.

According to a first aspect of the invention, a method for manufacturing a semiconductor device having a silicon-on-insulator region and a bulk region in a same semiconductor substrate, the method includes: (a) forming a protection film on the semiconductor substrate in the bulk region; (b) exposing a surface of the semiconductor substrate in the silicon-on-insulator region from under the protection film; (c) forming a first semiconductor layer and subsequently a second semiconductor layer on the semiconductor substrate in the silicon-on-insulator region and in the bulk region, using an epitaxy method after the step (a); (d) etching the first semiconductor layer and the second semiconductor layer partially, so as to form a first trench which exposes a side surface of the first semiconductor layer in the silicon-on-insulator region; (e) etching the first semiconductor layer through the first trench with an etching condition in which the first semiconductor layer is easier to be etched than the second semiconductor layer, so as to form a cavity between the semiconductor substrate and the second semiconductor layer in the silicon-on-insulator region; and (f) forming a buried insulating film inside the cavity.

In this case, the method may further include etching the second semiconductor layer and the first semiconductor layer partially, so as to form a second trench penetrating through the second semiconductor layer and the first semiconductor layer; and forming a support for supporting the second semiconductor layer at least inside the second trench; both steps included between the forming of the second semiconductor layer in the step (c) and the step (e).

In this case, the method may further include depositing an insulating layer on the entire surface of the semiconductor substrate, so as to bury the first trench after the step (f); and planarizing and removing the insulating layer from the top of the second semiconductor layer in the silicon-on-insulator region.

Here, the bulk region means either a region where an underlying layer thereof is composed only with a semiconductor substrate, or, a region composed only with a semiconductor substrate and with a semiconductor layer formed thereon. In the invention, an SOI structure means a structure in which a semiconductor layer is deposited on a buried insulating film, and a region in which the SOI structure is formed is also referred to as an “SOI region”.

According to the first aspect of the invention, the protection film protects the surface of the semiconductor substrate directly under the fine holes, even in the case where those holes are formed in the first and the second semiconductor layers (hereafter also referred to as “epitaxial film”) within the bulk region. Therefore, it is possible to prevent the surface of the semiconductor substrate to be exposed at the bottom surface of the hole, even when the insulating layer and the support are removed from the surface of the second semiconductor layer.

This prevents the surface of the semiconductor substrate from being etched through the fine holes, when removing the epitaxial film from the semiconductor substrate within the bulk area, thereby avoiding the formation of holes in the semiconductor substrate. Consequently, occurrences of defects, such as a leak current and a breakdown of a gate insulating film, are reduced in elements formed on the semiconductor substrate within the bulk region (i.e. bulk elements).

In the method according to the first aspect of the invention, the protection film is formed with a third semiconductor layer having one of an amorphous structure and a polycrystalline structure; and the step (a) includes: forming the third semiconductor layer over the semiconductor substrate with a chemical vapor deposition, having an insulating film therebetween; and etching the third semiconductor layer and the insulating film partially, so as to leave the third semiconductor layer in the bulk region on the semiconductor substrate and to expose the surface of the semiconductor substrate in the silicon-on-insulator region.

Here, according to the knowledge of the inventor, almost no fine holes are formed in the epitaxial film, if the epitaxial film formed on a semiconductor layer that is formed with the CVD method has an amorphous or a polycrystalline structure. Here, CVD stands for chemical vapor deposition. The CVD method referred to in aspects of the invention includes methods such as low-pressure CVD (LPCVD), atmospheric pressure CVD (APCVD), and plasma CVD (PCVD).

With theses methods, formation of fine holes in the epitaxial film in the bulk region is suppressed. Moreover, even if the fine holes are formed in this epitaxial film, the protection film protects the surface of the semiconductor substrate located directly thereunder. Therefore, it is possible to prevent the surface of the semiconductor substrate to be exposed at the bottom surface of the hole, at the time of removing the insulating layer from the surface of the second semiconductor layer.

In this case, the insulating layer is a silicon oxide film; and the protection film is a silicon nitride film. Here, the selection ratio of the silicon oxide (SiO₂ film) is higher than that of the silicon nitride (SiN) film in the wet etching using a diluted hydrofluoric acid solution (for instance, buffered hydrofluoric acid, or, BHF).

With this method, when removing the silicon oxide film from the surface of the second semiconductor layer, the SiN film protects the surface of the semiconductor substrate within the bulk region, thereby preventing the surface of the semiconductor substrate to be exposed at the bottom surface of the hole.

In this case, the method for manufacturing a semiconductor device according to the first aspect of the invention, further including: forming, prior to the step (a), an element isolation layer on the semiconductor substrate between the silicon-on-insulator region and the bulk region with a local-oxidation-of-silicon method. Here, the step (a) includes: partially etching an oxidation prevention film formed for forming the element isolation layer, the oxidation prevention film being formed over the semiconductor substrate in the silicon-on-insulator region and in the bulk region, so as to leave the oxidation prevention film over the semiconductor substrate in the bulk region as the protection film, as well as to remove the oxidation prevention film from over the semiconductor substrate in the silicon-on-insulator region and expose the surface of the semiconductor substrate. Here, LOCOS stands for local oxidation of silicon.

The increase in the number of processes is thereby suppressed, since the protection of the semiconductor substrate surface is carried out by utilizing the LOCOS method.

According to a second aspect of the invention, a method for manufacturing a semiconductor device having a silicon-on-insulator region and a bulk region in a same semiconductor substrate, the method includes: exposing a surface of the semiconductor substrate in the silicon-on-insulator region and the bulk region; forming a first semiconductor layer and subsequently a second semiconductor layer on the semiconductor substrate in the silicon-on-insulator region and in the bulk region, using an epitaxy method; etching the first semiconductor layer and the second semiconductor layer partially, so as to form a first trench which exposes a side surface of the first semiconductor layer in the silicon-on-insulator region; etching the first semiconductor layer through the first trench with an etching condition in which the first semiconductor layer is easier to be etched than the second semiconductor layer, so as to form a cavity between the semiconductor substrate and the second semiconductor layer in the silicon-on-insulator region; forming a buried insulating film inside the cavity; and removing the second semiconductor layer and subsequently the first semiconductor layer in the bulk region with etching, so as to expose the surface of the semiconductor substrate in the bulk region.

With this method, fine holes are not formed, since what is formed on the semiconductor substrate in the bulk region is the single-crystalline epitaxial film. Therefore, the occurrence of defect of bulk elements is reduced.

In this case, the method for manufacturing a semiconductor device further includes etching the surface of the semiconductor substrate in the silicon-on-insulator region, prior to forming the semiconductor layer, so that the surface of the semiconductor substrate in the bulk region and the surface of the second semiconductor layer in the silicon-on-insulator region have the same height when viewed sectionally.

With this method, the surface of the second semiconductor layer in the SOI region and the surface of the semiconductor substrate are aligned to the same height, thereby contributing to the planarization of the semiconductor device.

### BRIEF DESCRIPTION OF THE DRAWINGS

The invention will be described with reference to the accompanying drawings, wherein like numbers reference like elements.

FIGS. 1A and 1B are the first set of drawings illustrating a method for manufacturing a semiconductor device according to an embodiment of the invention.

FIGS. 2A to 2C are the second set of drawings illustrating the method for manufacturing a semiconductor device according to an embodiment of the invention.

FIGS. 3A and 3B are the third set of drawings illustrating the method for manufacturing a semiconductor device according to an embodiment of the invention.

FIGS. 4A and 4B are the fourth set of drawings illustrating the method for manufacturing a semiconductor device according to an embodiment of the invention.

FIGS. 5A and 5B are the fifth set of drawings illustrating the method for manufacturing a semiconductor device according to an embodiment of the invention.

FIGS. 6A to 6D are the sixth set of drawings illustrating the method for manufacturing a semiconductor device according to an embodiment of the invention.

FIGS. 7A to 7C are top view drawings illustrating another method for manufacturing a semiconductor device according to an embodiment of the invention.

FIGS. 8A to 8C are drawings illustrating a method for manufacturing a semiconductor device according to an alternative embodiment of the invention.

FIGS. 9A to 9C are drawings illustrating a method for manufacturing a semiconductor device according to another alternative embodiment of the invention.

FIGS. 10A to 10D are drawings illustrating a common method for manufacturing a semiconductor device.

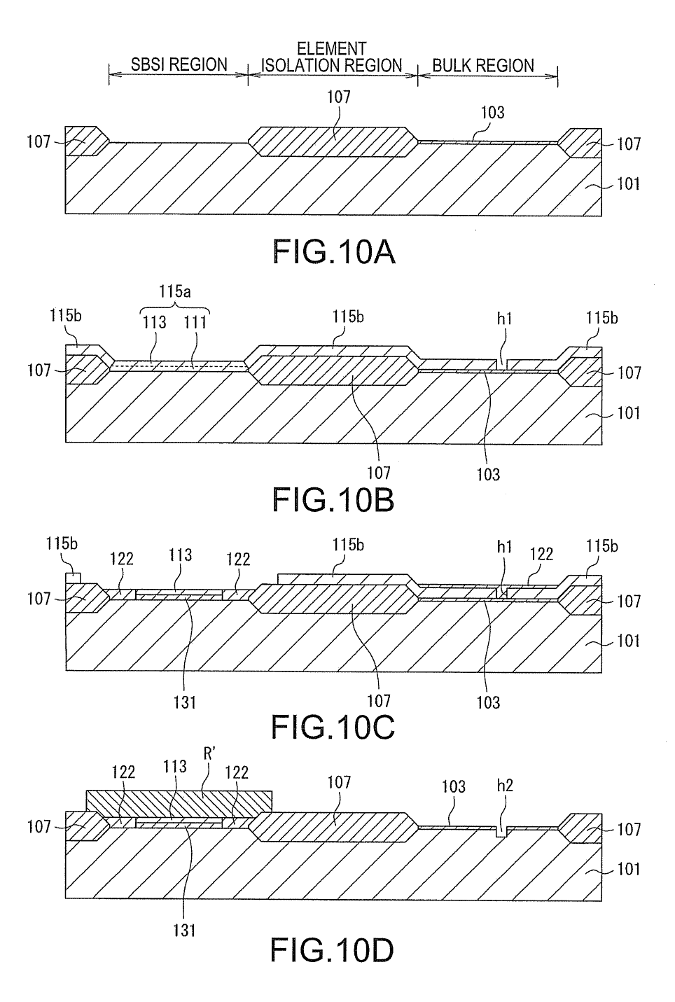

### DESCRIPTION OF EXEMPLARY EMBODIMENTS

A semiconductor device and a manufacturing method thereof according to aspects of invention will now be described with references to the accompanying drawings.

### First Embodiment

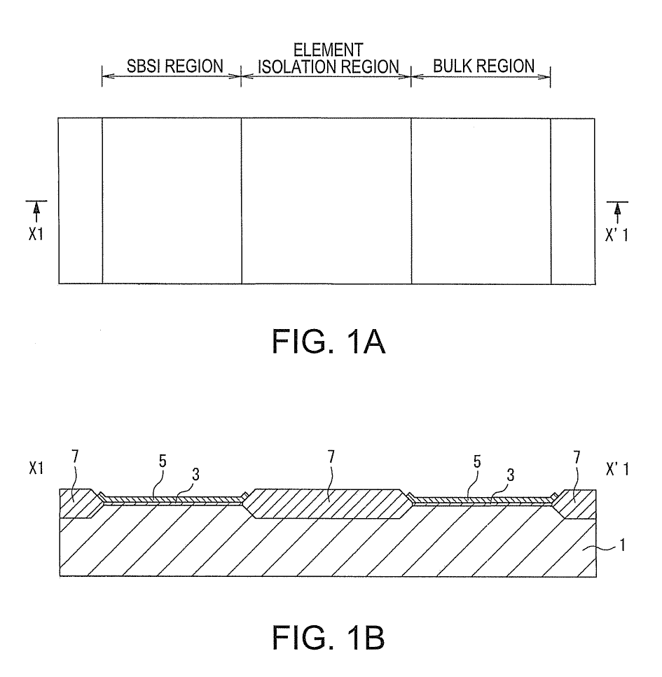

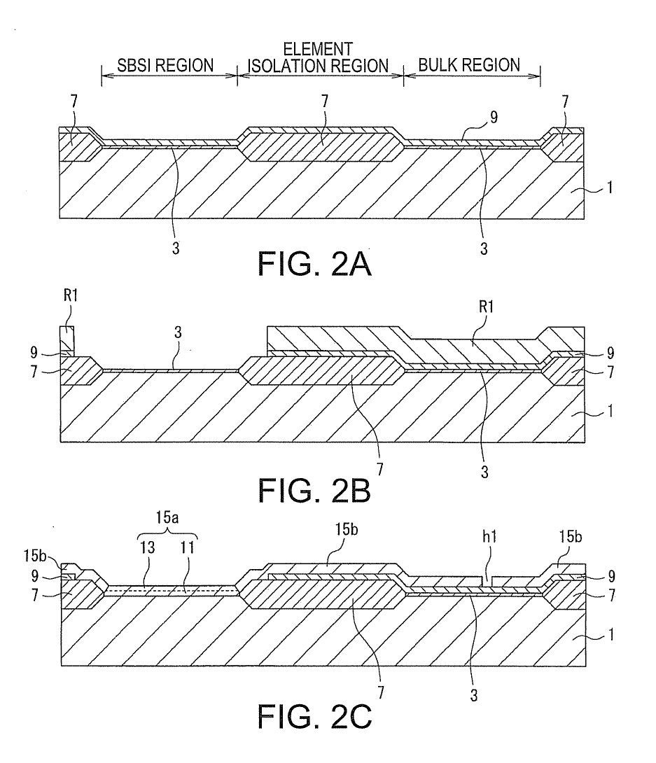

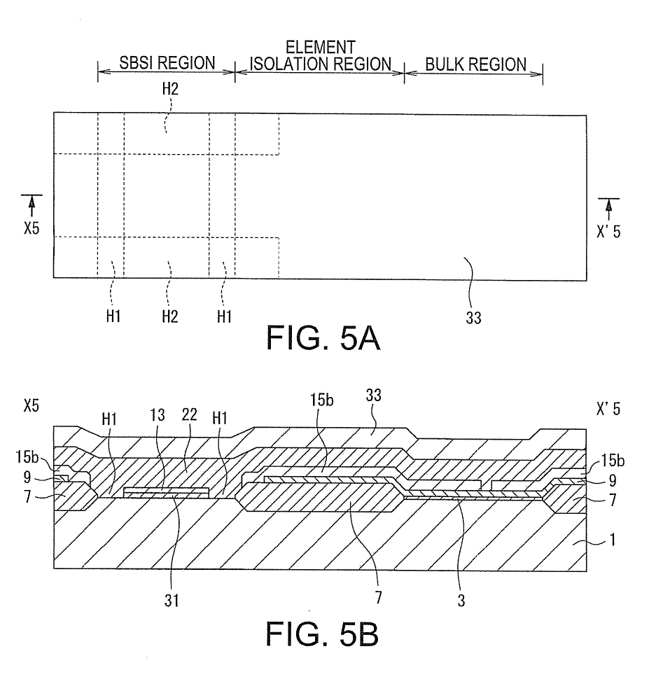

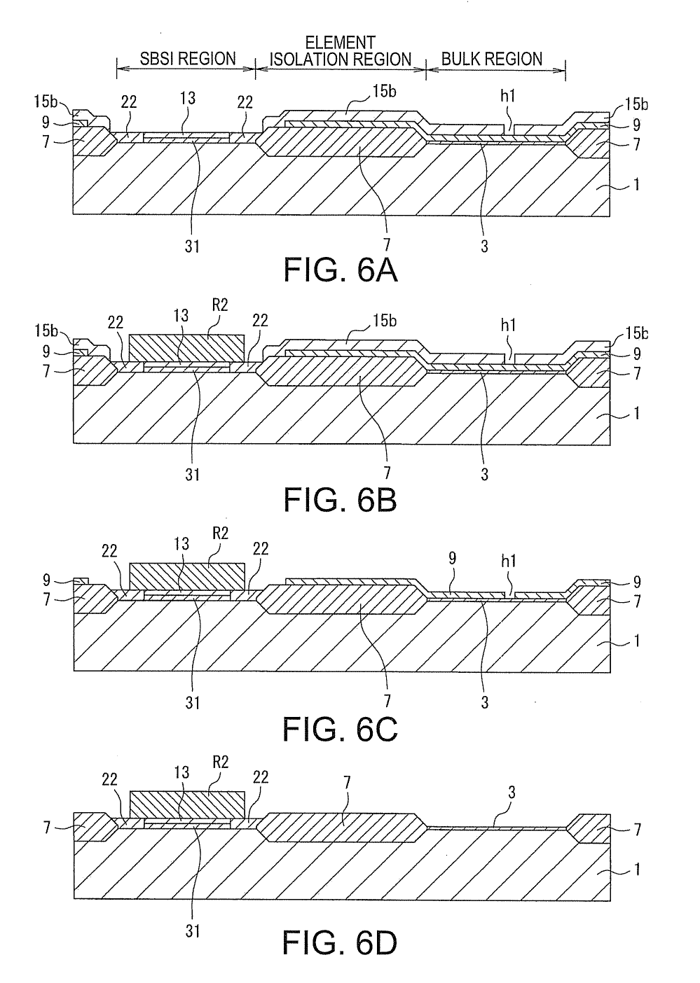

FIGS. 1A through 6D are drawings illustrating a method for manufacturing a semiconductor device according to a first embodiment. Specifically, FIGS. 1A, 3A, 4A, and 6A are plan views illustrating a method for manufacturing a semiconductor device according to the first embodiment, and FIGS. 1B, 3B, 4B, and 5B are sectional views of those respective plan views cut along the lines X1-X′1, X3-X′3, X4-X′4, and X5-X′5. FIGS. 2A through 2C are sectional views of a section X1-X′1, each view illustrating a process subsequent to the status shown in FIG. 1C. FIGS. 6A through 6D are sectional views of the section X5-X′5, each view illustrating a process subsequent to the status shown in FIG. 5C.

Referring now to FIGS. 1A and 1B, element isolation layers 7 are formed with LOCOS method on a silicon (Si) substrate 1 in element isolation regions present between an SBSI region and a bulk region; between one SBSI region and another, and between one bulk region and another. Specifically, a silicon oxidation (SiO₂) film 3 and a silicon nitride (SiN) film 5 are first formed on the entire top surface on the Si substrate 1, and thereafter, the surface of the Si substrate 1 within the element isolation regions are exposed by partially etching the SiN film S and the SiO₂ film 3 with a photolithography and etching techniques. Subsequently, a thermal oxidation is performed on the Si substrate 1 in a state in which the SBSI and bulk regions on the Si substrate 1 are covered with a film such as the SiN film S. The silicon substrate 7 is thereby formed in the element isolation regions on the Si substrate 1.

Here, the “SBSI region” according to this embodiment means a region in which the SBSI method is carried out, and this region includes an SOI region (a region in which an SOI structure is formed), a region in which support holes are formed, and a region in which trenches for removing SiGe are formed.

Subsequently, the SiN film 5 is removed from the SBSI region as well as from the bulk region by wet etching using an etchant such as a hot phosphoric acid solution. Referring now to FIG. 2A, an amorphous or polycrystalline Si layer 9 is then formed on the entire surface above the Si substrate 1 with CVD method. The thickness of the Si layer 9 is, for instance, approximately 100 nm.

Referring now to FIG. 2B, a resist pattern R1 is formed over the Si substrate 1 by a photolithography technique, the resist pattern R1 opening an area above the SBSI region and covering an area above the bulk region. The Si layer 9 is then removed by dry etching, using this resist pattern R1 as a mask. In this dry-etching process, Si has a higher selection ratio than that of the SiO₂. Therefore, the etching does not proceed to the SiO₂ film 3 in the SBSI region. The SiO₂ film 3 is then removed by wet-etching using an etchant such as BHF, so as to expose the surface of the Si substrate 1 in the SBSI region. Thereafter, the resist pattern R1 is removed by, for instance, ashing.

Referring now to FIG. 2C, a silicon germanium (SiGe) layer 11 and an Si layer 13, both having a single-crystalline structure, are sequentially deposited on the Si substrate 1. These SiGe layer 11 and Si layer 13 are formed continuously with, for instance, an epitaxy (hereafter, the SiGe layer 11 and the Si layer 13 are also collectively referred to as “pitaxial film”). At this time, an epitaxial film 15a having a single-crystalline structure is formed in the SBSI region on the Si substrate 1, and an epitaxial film 15b having a polycrystalline structure is formed on the SiO₂ film 3 in the bulk region as well as on the element isolation layer 7. As shown in FIG. 2C, there is a possibility that the fine holes h1 are formed in the polycrystalline 15b during its film deposition.

In this embodiment, a single-crystalline silicon buffer (Si-buffer) layer may be arranged in the SBSI region, between the Si substrate 1 surface and the epitaxial film 15a. In other words, the Si-buffer layer may be formed on the Si substrate 1 after removing the resist pattern R1, so as to subsequently deposit the SiGe layer 11 and the Si layer 13 thereron. These Si-buffer layer, SiGe layer 11, and Si layer 13 are formed continuously with, for instance, an epitaxy. Consequently, the single-crystalline Si-buffer layer is formed on the Si substrate 1 within the SBSI region, and the polycrystalline Si-buffer layer is formed on the SiO₂ film 3 within the bulk region as well as on the element isolation layer 7. As described, by providing the Si-buffer layer between the Si substrate 1 and the epitaxial film 15a, instead of directly forming the epitaxial film 15a on the Si substrate 1, the film quality of the epitaxial film 15a is improved (for instance, reduction of crystal defects).

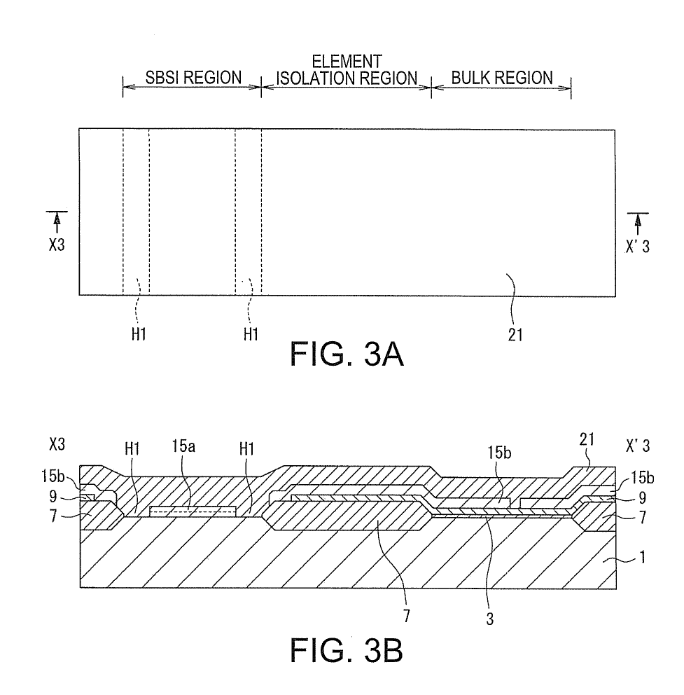

Subsequently, the epitaxial film 15a within the SBSI region is partially etched by a photolithography and an etching. This produces support holes H1, as shown in FIGS. 3A and 3B, the support holes H1 penetrating through the epitaxial film 15a, having the Si substrate 1 as a bottom surface. The etching process for forming the support holes H1, as shown in FIG. 3B, may either be stopped at the surface of the Si substrate 1, or, be continued to over etch the Si substrate 1 so as to form a concave.

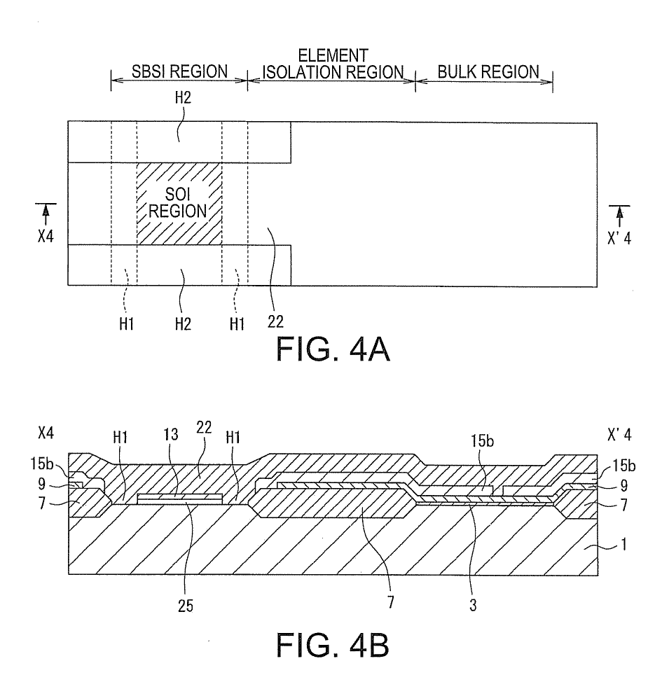

Thereafter, a support film 21 is formed on the entire surface above the Si substrate 1, so as to bury the support holes H1. The support film 21 is, for instance, an SiO₂ film. Subsequently, a partial etching of the support film 21 and of the epitaxial film 15a are carried out in that order using a photolithography and an etching technique. This process produces a support 22 formed from the support film 21, as well as trenches H2 which expose the side surfaces of SiGe layer and the Si layer 13, as shown in FIGS. 4A and 4B. An area surrounded with the support holes H1 as well as with the trenches H2 is the SOI region. In the etching process for forming the trenches H2, the etching of the SiGe layer may either be stopped in the middle so that a portion thereof may be left on the Si substrate 1, or, be over etched so that a concave may be formed in the Si substrate 1.

Thereafter, an etchant such as a fluoro-nitric acid solution contacts each side surface of the Si layer 13 and the SiGe layer 11 through the trenches H2, so as to selectively etch and remove the SiGe layer 11. Consequently, as shown in FIG. 4B, a cavity 25 is formed between the Si layer 13 and the Si substrate 1. In the wet etching using the fluoro-nitric acid solution, the etching ratio of SiGe is higher than that of Si (i.e. SiGe has a higher selection ratio compared to Si.). Therefore, it is possible to etch and remove only the SiGe layer while leaving the Si substrate 1 and the Si layer 13. At one point during the formation of the cavity 25, the top surface and the side surface of the Si layer 13 become supported by the support 22.

As shown in FIGS. 5A and 5B, the thermo oxidation of the Si substrate 1 and the Si layer forms an SiO₂ film (i.e. a BOX layer) 31 inside the cavity 25. In the process of thermo oxidation, an SiO₂ film grows from the top surface of the Si substrate 1 toward the interior of the cavity, and, at the same time, another SiO₂ film grows from the bottom surface of the Si layer 13 to the interior of the cavity. The SiO₂ films growing from the top as well as from the bottom are adhered tightly in the vicinity of a middle point in the height direction of the interior of the cavity, so as to form the BOX layer 31.

After forming the BOX layer 31, an insulating layer 33 is formed on the entire surface over the Si substrate 1 with methods such as CVD, so as to bury the trenches H2. The insulating layer 33 is, for instance, an SiO₂ film. Thereafter, the insulating layer 33 and the support 22 thereunder is planarized by, for instance, CMP. At this time, the polycrystalline epitaxial film 15b formed over the element isolation layer 7 functions as a stopper in the CMP processing.

Subsequently, the insulating layer 33 and the support 22 are removed by a wet etching with an etchant such as BHF. This exposes the surface of the Si layer (i.e. SOI layer) 13 within the SBSI region, as shown in FIG. 6A. Here, during the wet-etching process using BHF, the etching is carried out also on the insulating film and on the support 22 left in the bulk region. If the fine holes H1 are formed in the epitaxial film 15b inside the bulk region, the support 22 buried into this holes H1 is also removed by BHF. However, since the amorphous or polycrystalline Si layer 9 is formed at the bottom surface of these holes hi, the SiO₂ film 3 thereunder is not etched.

Referring now to FIG. 6B, a resist pattern R2 is formed over the Si substrate 1 by a photolithography technique, the resist pattern R2 covering at least the top surface of the SOI layer and exposing at least the top surface of the bulk region. The epitaxial film 15b is then removed by dry etching, using this resist pattern R2 as a mask. Consequently, as shown in FIG. 6C, the amorphous or polycrystalline Si layer 9 is entirely exposed from under the polycrystalline epitaxial film. The Si layer 9 is then removed by dry etching, using this resist pattern R2 as a mask.

Consequently, as shown in FIG. 6D, the SiO₂ film 3 is exposed from under the Si layer. In these dry-etching processes, the polycrystalline epitaxial film and the Si layer are etched with a higher selection ratio than that of the SiO₂ films. Therefore, even if the SiO₂ film 3 is exposed at the bottom surface of the holes before the epitaxial film and the Si layer are completely removed, the further etching of the SiO₂ film 3 is stopped, and thereby the exposure of the Si substrate 1 is prevented. As a result, it is possible to prevent the forming of the holes on the surface of the Si substrate 1 within the bulk region.

Subsequently, the SiO₂ film 3 is removed by wet etching using an etchant such as BHF, so as to expose the surface of the Si substrate 1 within the bulk region. The resist pattern R2 is then removed by, for instance, ashing. Thereafter, elements such as MOS transistors are formed on the SOI layer 13 and on the Si substrate 1 which is within the bulk region, by using, for instance, the common CMOS process.

According to the first embodiment of the invention, the Si layer 9 protects the surface of the Si substrate 1 directly under the holes H1 even in the case the holes H1 are formed in the polycrystalline epitaxial film 15b within the bulk region. Therefore, it is possible to prevent the surface of the Si substrate 1 to be exposed at the bottom surfaces of the holes h1, when the insulating layer 33 and the support 22 are removed from the top of the SOI layer 13.

This prevents the surface of the Si substrate 1 from being etched through the fine holes h1, when removing the epitaxial film 15b from the Si substrate 1 within the bulk area, thereby avoiding the formation of holes in the Si substrate 1. Consequently, occurrences of defects of the bulk elements, such as a leak current and a breakdown of a gate insulating film, are reduced.

Moreover, the epitaxy is a surface reaction, and the film quality of the epitaxial film is strongly affected by the status of an underlying film. In the first embodiment, the layer underlying the epitaxial film 15b is the Si layer 9 which has one of an amorphous and polycrystalline structures. Therefore, compared to the case where the underlying layer is the insulating film, the fine holes h1 are less likely to be formed.

In the first embodiment, the Si substrate 1, the SiGe layer 11, and the Si layer (SOI layer) 13 respectively correspond to the ‘semiconductor substrate’, the ‘first semiconductor layer’, and the ‘second semiconductor layer’ in the aforementioned aspects of the invention. Moreover, the SiO₂ film 3 and the amorphous or polycrystalline Si layer 9 respectively correspond to the “insulating film” and the “protection film”; the trenches H2 and the support holes H1 respectively correspond to a “first trench” and a “second trench”; and, the SiO₂ film (BOX layer) 31 and the insulating layer 33 respectively correspond to a “buried insulating film” and an “insulating layer” in the aforementioned aspects of the invention.

In the above-described first embodiment, a description is made for a case in which the amorphous or polycrystalline Si layer 9 is used as the “protection film” according to the aspects of the invention. However, the protection film of the invention is not limited thereto, and may be, for instance, a SiN film.

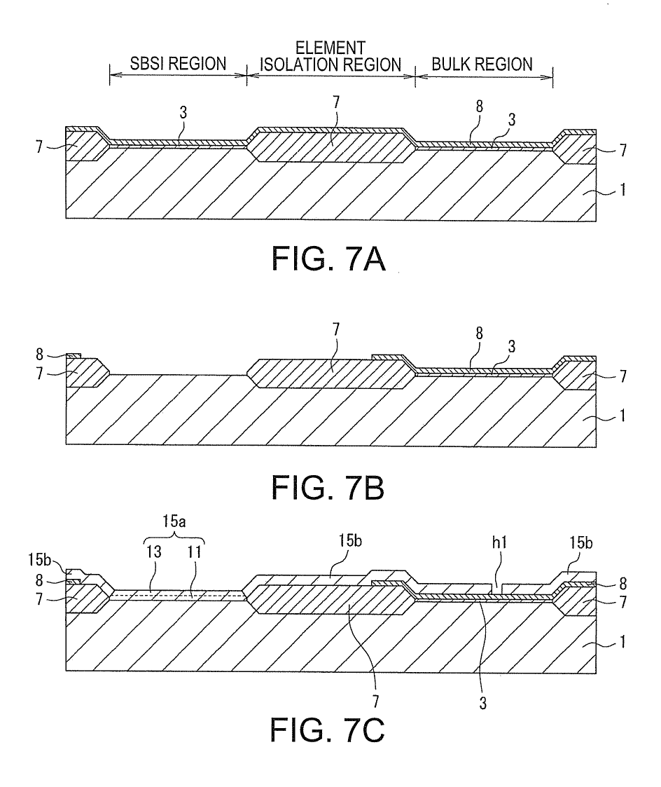

In this case, processes referred to in FIG. 7A include: forming the element isolation layer 7 with LOCOS method; removing the SiN film 5 (refer to FIGS. 1A and 1B for an example of the film) from the SBSI region and the bulk region, the SiN film 5 serving to prevent oxidation; followed by forming a SiN film 8 on the entire surface over the Si substrate 1. Thereafter, as shown in FIG. 7B, the SiN film 8 and the SiO₂ film 3 are removed from the Si substrate 1 in the SBSI region using photolithography and etching techniques, while leaving the SiN film 8 on the Si substrate 1 in the bulk region. The surface of the Si substrate 1 is thereby exposed within the SBSI region. Subsequently, as shown in FIG. 7C, an epitaxial film is formed on the entire surface above the Si substrate 1. The single-crystalline epitaxial film 16a is formed on the single-crystalline Si substrate 1, and a polycrystalline epitaxial film 15b is formed on the SiN film 8 as well as on the element isolation layer 7.

At this time, as shown in FIG. 7C, it is highly likely that the fine holes h1 are formed in the epitaxial film 15b during its deposition. However, the SiN film 8 is formed as an underlying layer. Therefore, it is possible to prevent the surface of the Si substrate 1 to be exposed in the bulk region, during the subsequent process to carry out wet-etching using etchants such as BHF. As a result, this prevents the forming of holes in the Si substrate 1 caused by the fine holes h1, when removing the polycrystalline epitaxial film 15b from the Si substrate 1 in the bulk area.

### Second Embodiment

In the first embodiment, the cases being described include forming one of the Si layer 9 and the SiN film 8 as a protection film, both having a polycrystalline structure, over the Si substrate 1 in the bulk region, after removing the SiN film 5 formed as an oxidation prevention film with LOCOS method. However, according to the aspects of the invention, part of the SiN film 5 for oxidation prevention may be used also as the protection film. The second embodiment describes this option.

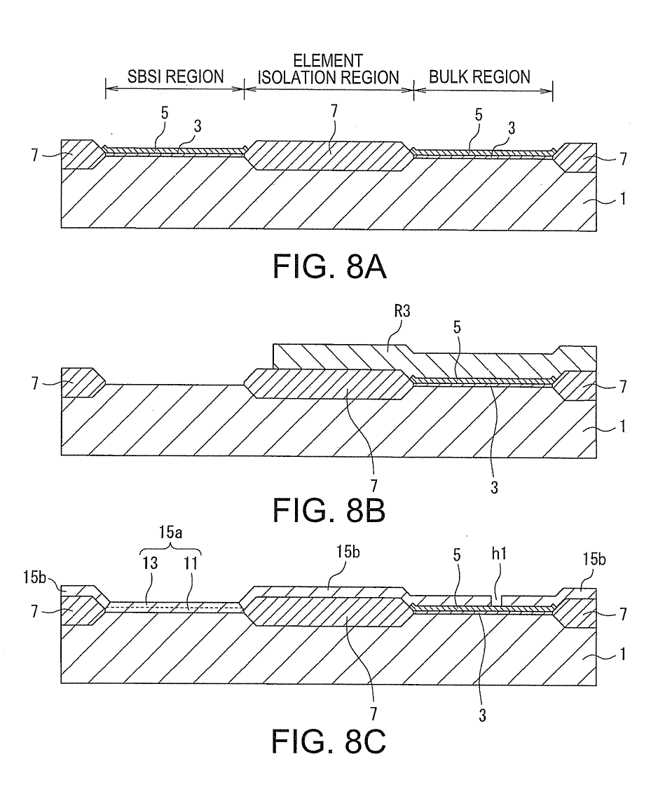

FIGS. 8A to 8C are sectional drawings illustrating a method for manufacturing a semiconductor device according to the second embodiment. The same signs and numerals as that of FIGS. 1A to 7C described in the first embodiment are used in FIGS. 8A to 8C for the parts having the same structures and properties as those of the first embodiment, and the detailed description thereof is omitted.

FIG. 8A illustrates a state after the element isolation layer 7 is formed with the LOCOS method. As shown in FIG. 8B, subsequent to forming the element isolation layer 7 as shown in FIG. 8A, a resist pattern R3 is formed over the Si substrate 1 by a photolithography technique, the resist pattern R3 opening an area above the SBSI region and covering an area above the bulk region. The SiN film 5 and the SiO₂ film 3 are then removed by dry etching, using this resist pattern R3 as a mask. This exposes the surface of the Si substrate 1 in the SBSI region, and the SiN film 5 which serves as an oxidation prevention film remains as is in the bulk region as a protection film. The method for removing the SiO₂ film 3 is not limited to dry etching, but may also include, for instance, wet etching using BHF. After removing the SiN film 5 and the SiO₂ film 3 from the SBSI region, the resist pattern R3 is removed by, for instance, ashing.

The rest of the process is the same as that of the first embodiment. In other words, as shown in FIG. 8C, an epitaxial film is formed on the entire surface above the Si substrate 1. The single-crystalline epitaxial film 16a is formed on the Si substrate 1 that has a single-crystalline structure, and a polycrystalline epitaxial film 15b is formed on the SiN film 5 as well as on the element isolation layer 7.

At this time, as shown in FIG. 8C, it is highly likely that the fine holes h1 are formed in the polycrystalline epitaxial films during the deposition thereof. However, the SiN film 5 is present thereunder, left as a protection layer. Therefore, it is possible to prevent the surface of the Si substrate 1 to be exposed in the bulk region, during the subsequent process to carry out wet-etching using etchants such as BHF.

As described, in the method for manufacturing a semiconductor device according to the second embodiment, utilizing the LOCOS method in this manner allows the protection of the surface of the Si substrate 1 in the bulk region. Therefore, the similar effect as that of the first embodiment is attained, while suppressing the increase in the number of processes (in other words, omitting one of the deposition of the Si layer 9 shown in FIG. 2A and the deposition of the SiN film 8 shown in FIG. 7A).

In the second embodiment, the SiN film 5 corresponds to both “oxidation prevention film” and “protection film” in the aspects of the invention. The rest of the relationships of components are the same as that of the first embodiment.

The method according to the second embodiment inherits the possibility that if the fine holes H1 are formed directly above a portion called a “bird beak” in the element isolation layer 7, in other words, in a vicinity of the boarder between the element isolation region and the bulk region, the bottom surfaces of the holes h1 cannot be protected with the SiN film 5, and the bird beak may be etched out with BHF. Therefore, in the case where it is necessary to protect not only the SiO₂ film 3 but also the bird beak, it is preferable to select the method according to the first embodiment described above, in spite of the increase in the number of processes. There is a trade-off between the effect of “reducing the number of processes” and “protecting also the bird beak”.

### Third Embodiment

In the first and the second embodiments, covering the bulk region with a protection film prevents the forming of holes in the layers under the protection film. However, according to another aspect of the invention, the forming of holes is prevented on the substrate surface in the bulk region, without forming the protection film. The third embodiment describes this option.

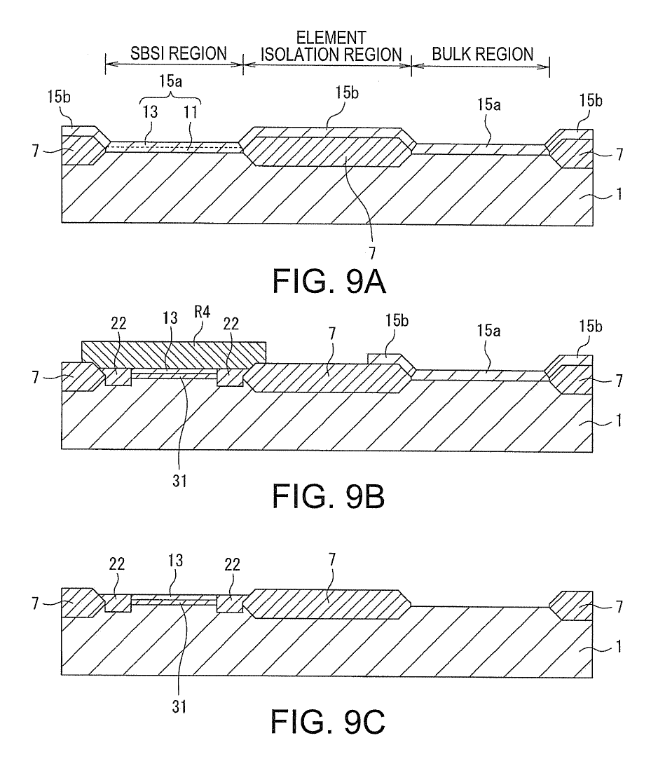

FIGS. 9A to 9C are sectional drawings illustrating a method for manufacturing a semiconductor device according to the third embodiment. The same signs and numerals as that of FIGS. 1A to 7C described in the first embodiment are used in FIGS. 9A to 9C for the parts having the same structures and properties as that of the first embodiment, and the detailed description thereof is omitted.

As shown in FIG. 9A, in the third embodiment, subsequent to forming the element isolation layer 7, the SiN film 5 and the SiO₂ film 3 (refer to FIG. 1A for both) for preventing oxidation are removed with etching. This exposes the entire surfaces of both the Si substrate 1 in the SBSI region and the Si substrate 1.

Subsequently, an epitaxial film is formed on the entire surface above the Si substrate 1. Here, in both the SBSI region and the bulk region, the surface of the single-crystalline Si substrate 1 is exposed. Therefore, the epitaxial film 16a is formed on those regions. That is to say, the single-crystalline epitaxial film 16a is formed also in the bulk region on the Si substrate 1. Therefore, the fine holes are not formed in the epitaxial film 16a in the bulk region. At the same time, the polycrystalline epitaxial film 15b is formed on the element isolation layer 7.

The same processes as that of the first embodiment is applied in the processes subsequent to the forming of the epitaxial films 16a and 15b, including planarizing the insulating film and the support 22.

As shown in FIG. 9B, an SOI structure is formed within the SBSI region on the Si substrate 1 with the SBSI method, the SOI structure composed with the SiO₂ film 31 and the Si layer 13. Thereafter, the insulating layer 33 is formed on the entire surface of the Si substrate 1 so as to bury the trenches H2 (for an example thereof, refer to FIGS. 5A and 5B). Subsequently, the insulating layer 33 and the support 22 thereunder is planarized by, for instance, CMP. At this time, the polycrystalline epitaxial film 15b formed over the element isolation layer 7 functions as a stopper in the CMP processing. The insulating layer 33 and the support 22 are then removed by wet etching with an etchant such as BHF. This exposes the surface of the Si layer (i.e. SOI layer) 13 in the SBSI region.

Referring back to FIG. 9B, a resist pattern R4 is formed over the Si substrate 1 by a photolithography technique, the resist pattern R4 covering at least an area over the SOI layer and exposing at least an area over the bulk region. The epitaxial film 15a in the bulk region is then removed by dry etching, using this resist pattern R4 as a mask. This exposes the surface of the Si layer 1 in the bulk region, as shown in FIG. 6C.

With the method for manufacturing a semiconductor device according to the third embodiment, fine holes are not formed, since what is formed on the Si substrate 1 in the bulk region is the single-crystalline epitaxial film 15a. Consequently, occurrences of defects, such as a leak current and a breakdown of a gate insulating film, are reduced in the bulk elements. The relationships of components between those in the third embodiment and those in the aspects of the invention are the same as that of the first embodiment.

In the method shown in FIGS. 9A to 9C, the level of the surfaces of the Si layer 13 and the Si substrate 1 in the bulk region are not aligned in the height direction. Therefore, the Si substrate in the SBSI region may be etched in advance, so that these surfaces will have the same height after the completion of the SOI structure. This etching process is carried out prior to the forming of the epitaxial films 15a and 15b. With this method, the level of the surfaces of the Si layer 13 and the Si substrate 1 within the bulk region is aligned to the same height, thereby contributing to the planarization of the semiconductor device.

What is claimed is:

1. A method for manufacturing a semiconductor device having a silicon-on-insulator region and a bulk region in a same semiconductor substrate, the method comprising:
(a) forming a protection film on the semiconductor substrate in the bulk region;
(b) exposing a surface of the semiconductor substrate in the silicon-on-insulator region from under the protection film;
(c) forming a first semiconductor layer and subsequently a second semiconductor layer on the semiconductor substrate in the silicon-on-insulator region and in the bulk region, using an epitaxy method after the step (a);
(d) etching the first semiconductor layer and the second semiconductor layer partially, so as to form a first trench which exposes a side surface of the first semiconductor layer in the silicon-on-insulator region;
(e) etching the first semiconductor layer through the first trench with an etching condition in which the first semiconductor layer is easier to be etched than the second semiconductor layer, so as to form a cavity between the semiconductor substrate and the second semiconductor layer in the silicon-on-insulator region; and
(f) forming a buried insulating film inside the cavity.

2. The method for manufacturing a semiconductor device according to claim 1, further comprising:
etching the second semiconductor layer and the first semiconductor layer partially, so as to form a second trench penetrating through the second semiconductor layer and the first semiconductor layer; and
forming a support for supporting the second semiconductor layer at least inside the second trench;
both steps included between the forming of the second semiconductor layer in the step (c) and the step (e).

3. The method for manufacturing a semiconductor device according to claim 1, further comprising:
depositing an insulating layer on the entire surface of the semiconductor substrate, so as to bury the first trench after the step (f); and
planarizing and removing the insulating layer from the top of the second semiconductor layer in the silicon-on-insulator region.

4. The method for manufacturing a semiconductor device according to claim 1, wherein:
the protection film is formed with a third semiconductor layer having one of an amorphous structure and a polycrystalline structure; and
the step (a) includes:
forming the third semiconductor layer over the semiconductor substrate with a chemical vapor deposition, having an insulating film therebetween; and
etching the third semiconductor layer and the insulating film partially, so as to leave the third semiconductor layer in the bulk region on the semiconductor substrate and to expose the surface of the semiconductor substrate in the silicon-on-insulator region.

5. The method for manufacturing a semiconductor device according to claim 1, wherein:
the insulating layer is a silicon oxide film; and
the protection film is a silicon nitride film.

6. The method for manufacturing a semiconductor device according to claim 1, further comprising:
forming, prior to the step (a), an element isolation layer on the semiconductor substrate between the silicon-on-insulator region and the bulk region with a local-oxidation-of-silicon method;
the step (a) including partially etching an oxidation prevention film formed for forming the element isolation layer, the oxidation prevention film being formed over the semiconductor substrate in the silicon-on-insulator region and in the bulk region, so as to leave the oxidation prevention film over the semiconductor substrate in the bulk region as the protection film, as well as to remove the oxidation prevention film from over the semiconductor substrate in the silicon-on-insulator region and expose the surface of the semiconductor substrate.

7. A method for manufacturing a semiconductor device having a silicon-on-insulator region and a bulk region in a same semiconductor substrate, the method comprising:
exposing a surface of the semiconductor substrate in the silicon-on-insulator region and the bulk region;
forming a first semiconductor layer and subsequently a second semiconductor layer on the semiconductor substrate in the silicon-on-insulator region and in the bulk region, using an epitaxy method;
etching the first semiconductor layer and the second semiconductor layer partially, so as to form a first trench which exposes a side surface of the first semiconductor layer in the silicon-on-insulator region;
etching the first semiconductor layer through the first trench with an etching condition in which the first semiconductor layer is easier to be etched than the second semiconductor layer, so as to form a cavity between the semiconductor substrate and the second semiconductor layer in the silicon-on-insulator region;
forming a buried insulating film inside the cavity; and
removing the second semiconductor layer and subsequently the first semiconductor layer in the bulk region with etching, so as to expose the surface of the semiconductor substrate in the bulk region.

8. The method for manufacturing a semiconductor device according to claim 7, further comprising etching the surface of the semiconductor substrate in the silicon-on-insulator region, prior to forming the semiconductor layer, so that the surface of the semiconductor substrate in the bulk region and the surface of the second semiconductor layer in the silicon-on-insulator region have the same height when viewed sectionally.
